(19) United States
(12) Patent Application Publication
(10) Pub. No.: US 2022/0328449 A1
(43) Pub. Date: Oct. 13, 2022

(54) Joining Method

(71) Applicant: Marelli Corporation, Saitama-city, Saitama (JP)

(72) Inventor: Teruyoshi Mihara, Saitama-city, Saitama (JP)

(21) Appl. No.: 17/616,353

(22) PCT Filed: May 29, 2020
(86) PCT No.: PCT/JP2020/021414

§ 371 Date: Dec. 3, 2021

(30) Foreign Application Priority Data
Jun. 6, 2019 (JP) 2019-106148

(51) Int. Cl. H01L 23/00

(52) U.S. Cl. CPC H01L 24/83; H01L 2224/83893

(57) ABSTRACT

Provided is a method that allows for firm joining of power module components even if a joining area is large. The method includes: forming an oxygen ion conductor layer on a surface of one of a first member to be joined containing metal and a second member to be joined containing ceramic; arranging the first member to be joined and the second member to be joined so that they are in contact with each other via the oxygen ion conductor layer; connecting the first member to be joined to one of a positive electrode side and a negative electrode side of a voltage application device and the second member to be joined to the other; and applying a voltage between the first member to be joined and the second member to be joined to join the first member to be joined and the second member to be joined together.

### CROSS-REFERENCE TO RELATED APPLICATION(S)

This application is a national stage 371 application of PCT/JP2020/021414, filed on May 29, 2020, which claims priority to and the benefit of Japanese Application Patent Serial No. 2019-106148, filed Jun. 6, 2019, the entire disclosures of which are hereby incorporated by reference.

### TECHNICAL FIELD

The present invention relates to a joining method.

### BACKGROUND

In recent years, the use of silicon carbide (SiC) has been considered as a next-generation power module material with a wide bandgap, which is expected to reduce power loss. Since the power module using the SiC is expected to operate at high temperatures (e.g., 300° C. or higher), joining of the elements composing the power module needs to be heat resistant.

The use of solder is one of the methods of joining the components, and the development of solder materials with heat resistance has been proceeded (see, for example, JP201572959 (A)). However, since soldering needs to be performed in a vacuum, it is necessary to perform batch processing to join components in a closed room, causing a problem of poor handling. Further, solder materials with high melting points are easily oxidized and have poor wettability, resulting in poor soldering.

On the other hand, examples of a joining method that can be performed in the atmosphere include a method using powder metallurgy such as silver sinter (see, for example, JP2011236494 (A)) or copper sinter (see, for example, JP201391835 (A)), which have been put into practical use in the bonding of semiconductor chips.

### SUMMARY

In the method using a sinter as disclosed in JP2011236494 (A) and JP201391835 (A), it is necessary to apply pressure uniformly to a joining surface before starting the joining, but it is difficult to apply pressure uniformly when the area of the joining surface is large.

In light of the aforementioned problem, it would be thus helpful to provide a joining method to firmly join the components of the power module even when the area of joining surface is large.

A joining method according to a first aspect to solve the above problem includes: an oxygen ion conductor layer formation step of forming an oxygen ion conductor layer on a surface of one of a first member to be joined containing metal and a second member to be joined containing ceramic;

an arrangement step of arranging the first member to be joined and the second member to be joined so that they are in contact with each other via the oxygen ion conductor layer;

a connection step of connecting the first member to be joined to one of a positive electrode side and a negative electrode side of a voltage application device and connecting the second member to be joined to the other of the positive electrode side and the negative electrode side of the voltage application device; and

a voltage application step of applying a voltage between the first member to be joined and the second member to be joined to join the first member to be joined and the second member to be joined.

According to the present invention, the components of the power module can be firmly joined even when an area of the joining surface is large.

### BRIEF DESCRIPTION OF THE DRAWINGS

In the accompanying drawings:

FIG. 1 is a flowchart of a joining method according to the present invention;

FIG. 2A is a diagram illustrating Example 1;

FIG. 2B is a diagram illustrating Example 1;

FIG. 3A is a diagram illustrating Example 2;

FIG. 3B is a diagram illustrating Example 2;

FIG. 4A is a diagram illustrating Example 3;

FIG. 4B is a diagram illustrating Example 3;

FIG. 5A is a diagram illustrating Example 4;

FIG. 5B is a diagram illustrating Example 4;

FIG. 6A is a diagram illustrating Example 5;

FIG. 6B is a diagram illustrating Example 5;

FIG. 7A is a diagram illustrating Example 6;

FIG. 7B is a diagram illustrating Example 6;

FIG. 8A is a diagram illustrating Example 7;

FIG. 8B is a diagram illustrating Example 7;

FIG. 9A is a diagram illustrating Example 8;

FIG. 9B is a diagram illustrating Example 8;

FIG. 10A is a diagram illustrating Example 9; and

FIG. 10B is a diagram illustrating Example 9.

### DETAILED DESCRIPTION

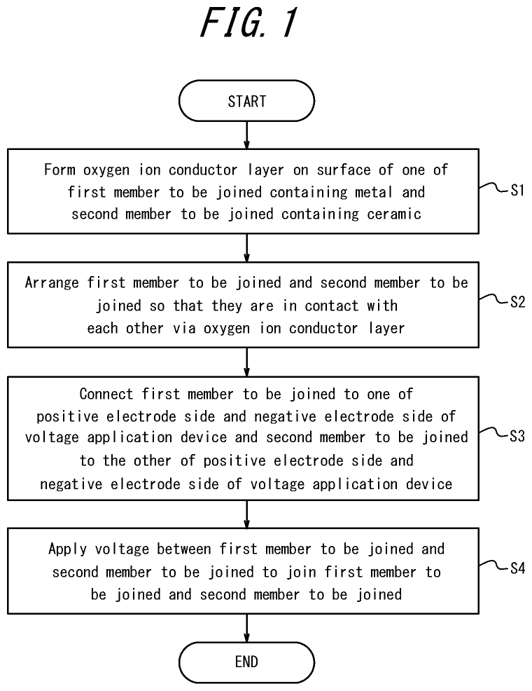

The joining method according to the present invention will be described below with reference to the drawings. FIG. 1 illustrates a flowchart of the joining method according to the present invention. The joining method according to the present invention includes: an oxygen ion conductor layer formation step (step S1) of forming an oxygen ion conductor layer on a surface of one of a first member to be joined containing metal and a second member to be joined containing ceramic; an arrangement step (step S2) of arranging the first member to be joined and the second member to be joined so that they are in contact with each other via the oxygen ion conductor layer; a connection step (step S3) of connecting the first member to be joined to one of a positive electrode side and a negative electrode side of a voltage application device and connecting the second member to be joined to the other of the positive electrode side and the negative electrode side of the voltage application device; and a voltage application step (step S4) of applying a voltage between the first member to be joined and the second member to be joined to join the first member to be joined and the second member to be joined.

As described above, when the components of the power module are joined, a method using solder is not easy to handle because it needs to be performed in a vacuum. Further, the method has problems of oxidation and wettability of the solder material. In the method using silver sinter or copper sinter, it is difficult to uniformly apply pressure to the joining surface when an area of joining surface is large.

The components of the power module include a base plate, a cooling plate, a multilayer circuit board, an external connection terminal, and the like. Of these components, the base plate, an internal wiring layer in the multilayer circuit board, and the external connection terminal are made of metal. Further, a circuit board such as a power module board is mainly made of ceramic. That is, the joining between the components of the power module is mainly the joining between metal and ceramic.

Thus the present inventor diligently studied ways to firmly join metal and ceramic over a large area, and as a result, found that, when an oxygen ion conductor is interposed, the metal and the ceramic can be joined firmly by applying a voltage therebetween.

Specifically, an oxygen ion conductor layer was formed on the surface of the metal, the metal and the ceramic were brought in contact with each other via the oxygen ion conductor layer, and then the metal was connected to the positive electrode side of the voltage application device and the ceramic was connected to the negative electrode side of the voltage application device. Then, when a DC voltage was applied between the metal and the ceramic, they were joined firmly.

The reason why the above-mentioned firm joining is formed is considered as follows. That is, when a voltage is applied between the metal and the ceramic, a strong electrostatic force is exerted by the positive charge and the negative charge induced by contact, and the oxygen ion conductor layer formed on the surface of the metal and the ceramic come close to each other to an atomic level distance and adhere to each other. Then, between the oxygen ion conductor (X—O) constituting the oxygen ion conductor layer and the ceramic (R—O), a reduction reaction as shown in the following formula (1) occurred and a covalent bond was formed.

X—O+R—O+2e→X—O—R+O²— (1)

According to the above-described reduction reaction, the oxide constituting the ceramic (R—O) is reduced, and a bond (X—O—R) is formed between the material (R) of the reduced oxide and the oxygen ion conductor (X—O), and as a result, the oxygen ion conductor and the ceramic are firmly joined on the contact surface.

On the other hand, the O²— ions generated in the above-mentioned reduction reaction move through the oxygen ion conductor layer to the anode side and are discharged. In this manner, it is considered that, as a result of the reduction reaction occurred in the ceramic on the cathode side, a firm joint was formed between the oxygen ion conductor and the ceramic, and eventually between the metal and the ceramic.

The reduction reaction represented by the above formula (1) is considered to be a reaction in contrast to the electrochemical reaction that occurs in the conventional anode bonding method. That is, when the glass (X—O—Na) and the metal (M) are joined by the anode bonding method, for example, it is considered that the oxidation reactions as shown in the following formulae (2) to (4) occur between the glass (X—O—Na) and the metal (M).

X—O—Na→X—O—+Na⁺ (2)

X—O⁻+M→X—O-M+e (3)

Na⁺+e→Na (4)

The reactions shown in the above formulae (2) and (3) are reactions that occur on the anode side (contact interface), and Na is ionized and desorbed to generate X—O—, which is bonded with M and a joint is formed. On the other hand, the reaction of the formula (4) is a reduction reaction that occurs on the negative electrode side, and Na+ that has moved through the glass toward the cathode side receives electrons and is reduced to Na.

In this manner, the joining method according to the present invention based on the reduction reaction at the cathode is a joining method that is new and in contrast to the conventional anode bonding method based on the oxidation reaction at the anode, and is referred to as a “cathode bonding method” as opposed to the conventional anode bonding method. According to this cathode bonding method, the oxygen ion conductor and the ceramic, and eventually the metal and the ceramic can be joined firmly.

Further, as obvious from the above formulae from (2) to (4), Na⁺ carries electricity in the glass, and there is no contribution of free O²⁻. Since Na is deposited on the cathode side, it may cause contamination, and if the glass has a plated surface, it may cause plating peeling at the interface. In this respect, in the present invention, since O²⁻ takes the role of oxygen ion conduction, and thus a joining corresponding to both oxidation and reduction is formed. Since oxygen is a gas, the problems of contamination and plating peeling that occur in the reaction in the glass will not occur.

In the above specific example, the oxygen ion conductor layer is formed on the surface of the metal, but it was also found that the metal and the ceramic could be firmly joined even when the oxygen ion conductor layer was formed on the surface of the ceramic. However, in this case, it was found that it was necessary to connect the metal to the negative electrode side of the voltage application device and the ceramic to the positive electrode side of the voltage application device to reverse the polarity of the voltage.

In this case as well, it is considered that the same electrochemical reaction as the above-described cathode bonding has occurred. That is, a natural oxide film (M-O), which is generally an oxide layer, is formed on the surface of the metal (M) constituting the power module. Thus, it is considered that, when a voltage is applied between the oxygen ion conductor layer and the ceramic, the reduction reaction shown in the formula (5) below occurs between the oxygen ion conductor (X—O) and the natural oxide film (M-O).

X—O+M-O+2e→X—O-M+O²— (5)

According to the above-described reduction reaction, the metal oxide constituting the natural oxide film (M-O) is reduced, and a bond (X—O-M) is formed between the metal (M) of the reduced metal oxide and the oxygen ion conductor (X—O), and as a result, the metal and the oxygen ion conductor, and eventually the metal and the ceramic are firmly joined on the contact surface.

Furthermore, the present inventor found that, even when the natural oxide film on the surface of the metal is removed by polishing or when the natural oxide film such as gold is difficult to be formed, the metal and the ceramic are firmly joined when the metal is connected to the positive electrode side of the voltage application device and the ceramic is connected to the negative electrode side of the voltage application device and a voltage is applied.

The reason why the above-described firm joining is formed is considered that, when a voltage is applied between the oxygen ion conductor and the metal, oxidation reactions as shown below in formulae (6) to (8) occur between the oxygen ion conductor (X—O) and the metal (M).

X—O+O²-+M→X—O₂-M+2e (6)

O²-+M→M-O+2e (7)

X—O+O²⁻+M-O→X—O₃-M+2e (8)

Due to the oxidation reaction described above, it is considered that, on the contact surface between the oxygen ion conductor (X—O) and the metal (M), the oxygen ions that entered the oxygen vacancies emitted electrons to form a new firm bonding (X—O₃-M) with the metal (M) and the oxygen ion conductor (X—O), and as a result a firm joining was formed on the contact surface.

In this manner, the present inventor has found out that the metal and the ceramic can be joined firmly via the oxygen ion conductor, and completed the present invention. Each step of the present invention will be described below.

First, in step S1, an oxygen ion conductor layer is formed on the surface of one of a first member to be joined containing metal and a second member to be joined containing ceramic (oxygen ion conductor layer formation step).

The first member to be joined in the present invention may be a member containing metal such as a base plate, an internal wiring layer in a multilayer wiring board, and an external connection terminal constituting a power module. Of these, the base plate can be made of aluminum, copper, stainless steel (SUS), or the like. Further, the internal wiring layer and the external connection terminal may be made of copper (Cu), aluminum (Al), nickel (Ni), titanium (Ti), tungsten (W) or the like.

An oxide layer may be formed on the surface of the metal. This oxide layer may be a natural oxide film of a metal constituting the first member to be joined. Further, an oxide film of a metal different from the metal constituting the first member to be joined may be formed on the surface of the first member to be joined.

When the first member to be joined is the internal wiring layer of the wiring board, the internal wiring layer may be covered with a glass frit layer formed by softening and then curing a glass frit. Since the glass frit is mainly composed of silicon oxide (Si—O), the silicon oxide is reduced by the cathodic bonding method described above, and the oxygen ion conductor (X—O) and the silicon oxide (Si—O) are firmly joined on the contact surface.

The ceramic constituting the second member to be joined is not particularly limited, and can be used, for example, as a power module substrate for mounting a power module. Such ceramic can typically be made of a ceramic material such as alumina or mullite, and examples include titania, yttria, magnesia, alumina, silica, and chromia.

The oxygen ion conductor layer is a layer that allows oxygen ions to permeate. The material of the oxygen ion conductor layer is not particularly limited as long as it allows oxygen ions to permeate, but an oxide ion conductor is preferable. For example, stabilized zirconia (YSZ) doped with zirconia (ZrO₂) or yttria (Y₂O₃), neodymium oxide (Nd₂O₃), samaria (Sm₂O₃), gadolinium (Gd₂O₃), and scandia (Sc₂O₃) can be used. Further, bismuth oxide (Bi₂O₃), cerium oxide (CeO), zirconium oxide (ZrO₂), lanthanum gallate oxide (LaGaO₃), indium barium oxide (Ba₂In₂O₅), nickel lanthanum oxide (La₂NiO₄), and potassium nickel fluoride (K₂NiF₄), etc., can also be used.

The material constituting the oxygen ion conductor layer is not limited to the above, and other known oxygen ion conductor materials can be used. Further, these materials may be used alone or in combination of a plurality of types.

The above-described oxygen ion conductor layer can be formed on the first member to be joined or the second member to be joined by various known methods in which ceramic particulates or vaporized ceramic particulates are directly stacked on the surface. Specifically, the layer can be formed under appropriate deposition conditions using thermal spraying, sputtering, chemical vapor deposition (CVD), physical vapor deposition (PVD), cold spray, and other methods.

When the metal that constitutes the first member to be joined is Cu or SUS, which is relatively hard, a plating layer as a buffer layer may be formed on the surface of one of the first member to be joined and the second member to be joined. As the material constituting the plating, conventionally known materials may be used, and gold plating, silver plating and the like can be used.

In the present invention, the contact surfaces of the oxygen ion conductor layer and the first member to be joined or the second member to be joined are firmly attracted to each other through the electrostatic attraction, by applying a high voltage of several hundreds of volts. When the contact surfaces approach each other to an about interatomic distance, a covalent bond is formed between atoms of the contact surfaces approached each other through the above-mentioned electrochemical reaction. Therefore, the flatness of the surface to be joined is important, and it is desirable to finish the surface as mirror-like as possible. Specifically, it is preferable that the contact surface between the oxygen ion conductor layer and the first member to be joined or the second member to be joined is finished flat by the mirror polishing treatment, or that the oxygen ion conductor layer and at least one of the first member to be joined or the second member to be joined are formed thin so that they can be in close contact with each other. As a result, the joining strength between the oxygen ion conductor layer and the first member to be joined or the second member to be joined can be increased.

Next, in step S2, the first member to be joined and the second member to be joined are arranged so that they come in contact with each other via the oxygen ion conductor layer (arrangement step).

Subsequently in step S3, the first member to be joined is connected to one of the positive and negative electrode sides of the voltage application device, and the second member to be joined is connected to the other of the positive and negative electrode sides of the voltage application device (connection step).

In this step, which of the first member to be joined and the second member to be joined is connected to the positive electrode side of the voltage application device depends on whether the material in contact with the oxygen ion conductor layer contains oxygen or not in the above arrangement step.

Specifically, when the material in contact with the oxygen ion conductor layer contains oxygen, one of the first and second materials to be joined on which the oxygen ion conductor layer is formed is connected to the positive electrode side of the voltage application device, and the other is connected to the negative electrode side of the voltage application device.

On the other hand, when the material in contact with the oxygen ion conductor layer does not contain oxygen, one of the first and second materials to be joined on which the oxygen ion conductor layer is formed is connected to the negative electrode side of the voltage application device, and the other is connected to the positive electrode side of the voltage application device.

In the connection step, the positions of the first member to be joined and the second member to be joined that are connected to the voltage application device are not limited, and it suffices if a joint can be formed at the contact interface between the first member to be joined and the second member to be joined in step S4 described below.

Subsequently, in step S4, a voltage is applied between the first member to be joined and the second member to be joined to join the first member to be joined and the second member to be joined (voltage application step). Specifically, a DC voltage is applied between the first member to be joined and the second member to be joined while heating the first member to be joined and the second member to be joined.

The ceramic constituting the second member to be joined becomes conductive as the temperature rises. Further, the oxygen ion conductor constituting the oxygen ion conductor layer increases in oxygen ion conductivity as the temperature rises, allowing electricity to flow therethrough. As a result, the oxygen ion conductor layer and the first member to be joined or the second member to be joined, and eventually, the first member to be joined and the second member to be joined are joined.

Since the resistance values of the ceramic constituting the second member to be joined and the oxygen ion conductor constituting the oxygen ion conductor layer change depending on the working temperature, the voltage applied between the first member to be joined and the second member to be joined has an optimum range depending on the temperature. The voltage should be selected to be optimal for the application, considering the material properties of the ceramic and oxygen ion conductor and the operating conditions after joining. If the working temperature or the voltage is too low, the current flowing through the ceramic and the oxygen ion conduction current of the oxygen ion conductor will decrease, and the time required for joint formation will increase. On the other hand, when the temperature is high, the time required for joint formation will decrease, but the residual stress after joining increases, which is unsuitable from the viewpoint of durability. With respect to the voltage, when it is too high, discharge to the portions other than the joining portion will occur, making joining difficult. Typically, it is preferable to select the optimum value in the range of voltage of 50 V or more and 500 V or less under the temperature conditions of 300° C. or more and 500° C. or less. As a result, the oxygen ion conductor layer and the first member to be joined or the second member to be joined, eventually the first member to be joined and the second member to be joined can be more firmly joined.

Next, the approximate time for applying a voltage between the first member to be joined and the second member to be joined will be described. In the present invention, the optimal time can be determined by focusing on a change in the current value. Shortly after the start, while the joining formation area between the oxygen ion conductor layer and the first member to be joined or the second member to be joined is expanding, the current value shows an increasing tendency as an average current while repeating a slight increase and decrease. Then, when joining is almost completed, the average current starts to decrease. It is preferable that the point at which the current value starts to decrease is used as a guide to stop application of a voltage. As a result, the first member to be joined and the second member to be joined can be firmly joined over the entire joining surface.

As described above, the temperature at which joining is performed is approximately 300° C. or more and 500° C. or less, but an appropriate temperature can be set based on the charge required to form covalent bond between atoms of the surface layer through electrolysis at the joining interface between the first member to be joined and the second member to be joined.

That is, the charge Q(C) required to form a covalent bond at the joining interface is given by the following equation (9):

Q=qSNs (9)

where q is an elementary charge (1.6×10⁻¹⁹(C)), S is an area of the joining interface (cm²), and Ns is an atomic planar density (cm⁻²).

On the other hand, the notation for the above charge Q from the circuit equation is as shown in the equation (10) below:

Q=It=Vt/R (10)

where R is a resistance value (Ω) of the circuit (that is, ceramic), V is a voltage (V) applied between the first member to be joined and the second member to be joined, and t is a voltage application time, that is, a joining time (s).

From the equation (10), the resistance value R (Ω) of the ceramic is given by the following equation (11):

R=Vt/Q (11).

Assuming that the resistivity of the ceramic is ρ(Ω·cm), ρ is given by the following equation (12):

ρ=RS/d (12),

provided that d is the thickness (cm) of the ceramic.

From the above equations (9), (10) and (12), the resistivity ρ is given by the following equation (13):

$$ρ = \frac{Vt}{qdNs} \qquad ( 13 )$$

For example, from the calculation, it was found that the resistivity p of the ceramic required to join alumina plate having an area of 1 cm2 and a thickness of 1 mm within 100 seconds at a voltage of 100 V should be 6.2 MΩ·cm or less. Since the resistivity of the ceramic decreases at high temperatures, it may be joined by selecting a temperature at which the resistivity ρ is 6.2 MΩ·cm or less.

As described above, according to the joining method of the present invention, since the means for externally pressurizing as used in the past is not required, the components of the power module can be firmly joined even when the area of the joining surface is large.

### EXAMPLES

Examples of the present invention will be described below, but the present invention is not limited to the examples.

### Example 1

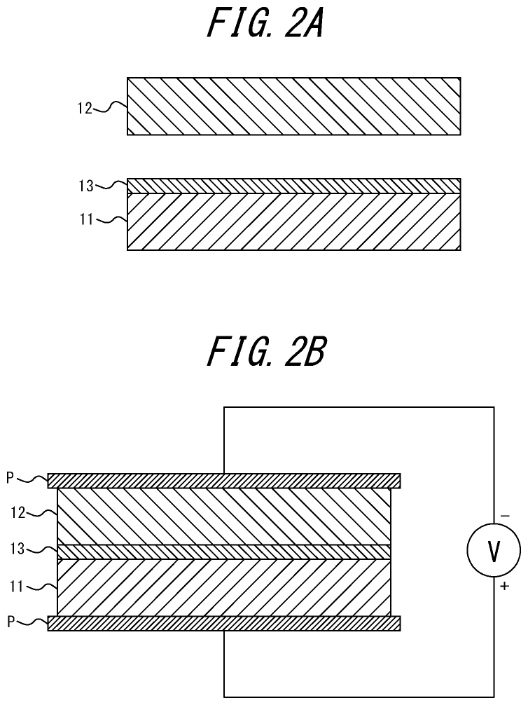

The base plate and the power module substrate constituting the power module were joined together. First, the base plate 11 made of aluminum and the power module substrate 12 made of alumina were prepared. Then, as illustrated in FIG. 2A, the oxygen ion conductor layer 13 made of YSZ was formed on the surface of the base plate 11. Next, as illustrated in FIG. 2B, the base plate 11 was brought in contact with the electrode plate P connected to the positive electrode side of the voltage application device V, and the power module substrate 12 was brought in contact with the electrode plate P connected to the negative electrode side of the voltage application device V. Then, with the base plate 11, the power module substrate 12, and the oxygen ion conductor layer 13 heated to 500° C., a DC voltage of 100 V was applied between the base plate 11 and the power module substrate 12. As a result, the base plate 11 and the power module substrate 12 were firmly joined together (cathode bonding).

### Example 2

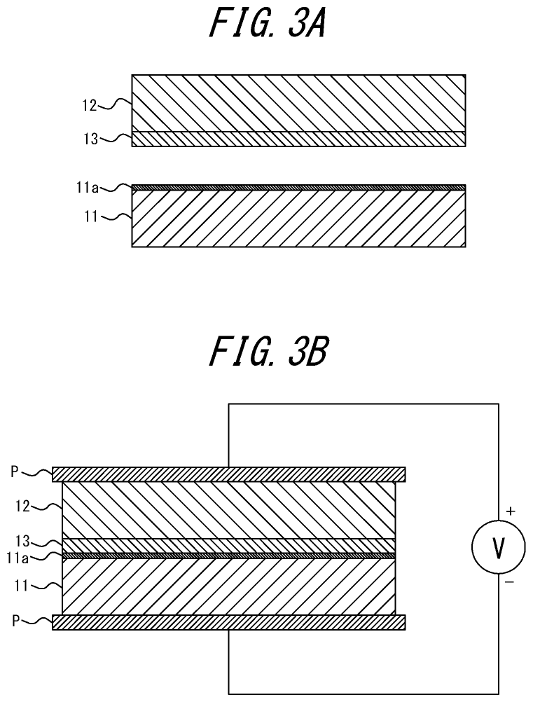

As with Example 1, the base plate and the power module substrate constituting the power module were joined together. However, as illustrated in FIG. 3A, the oxygen ion conductor layer 13 was formed on the surface of the power module substrate 12. Here, on the surface of the base plate 11, the natural oxide film 11a (oxide layer) made of aluminum constituting the base plate 11 was formed. Then, as illustrated in FIG. 3B, the base plate 11 was brought in contact with the electrode plate P connected to the negative electrode side of the voltage application device V and the power module substrate 12 was brought in contact with the electrode plate P connected to the positive electrode side of the voltage application device V. As a result, the base plate 11 and the power module substrate 12 were firmly joined together.

### Example 3

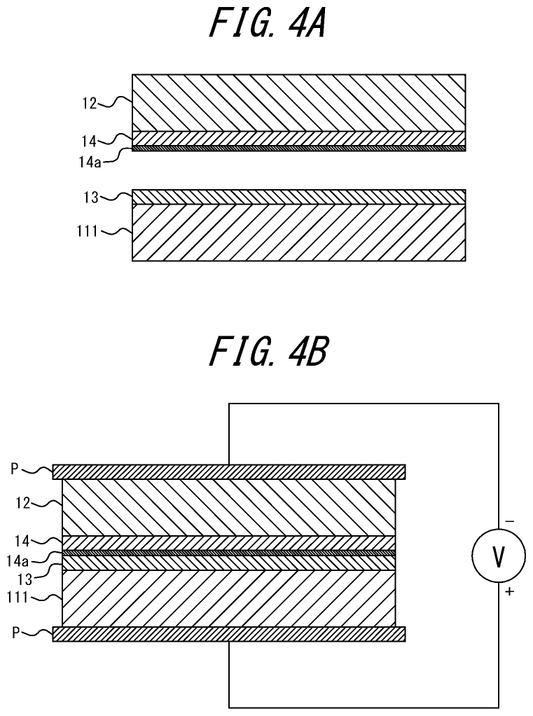

As with Example 1, the base plate and the power module substrate constituting the power module were joined together. However, the base plate 111 was made of SUS, which is harder than aluminum, and as illustrated in FIG. 4A, the plating layer 14 made of copper is formed on the surface of the power module substrate 12. Here, the natural oxide film (oxide layer) 14a made of copper constituting the plating layer 14 was formed on the surface of the plating layer 14. Then, as illustrated in FIG. 4B, the base plate 111 and the power module substrate 12 were arranged so that they are in contact with each other via the oxygen ion conductor layer 13 and the plating layer 14. Subsequently, the base plate 111 was brought in contact with the electrode plate P connected to the positive electrode side of the voltage application device V and the power module substrate 12 was brought in contact with the electrode plate P connected to the negative electrode side of the voltage application device V, and a DC voltage was applied between the base plate 111 and the power module substrate 12. As a result, the base plate 111 and the power module substrate 12 were firmly joined together (cathode bonding). In this manner, formation of a plating layer allows even hard materials to be uniformly joined together.

### Example 4

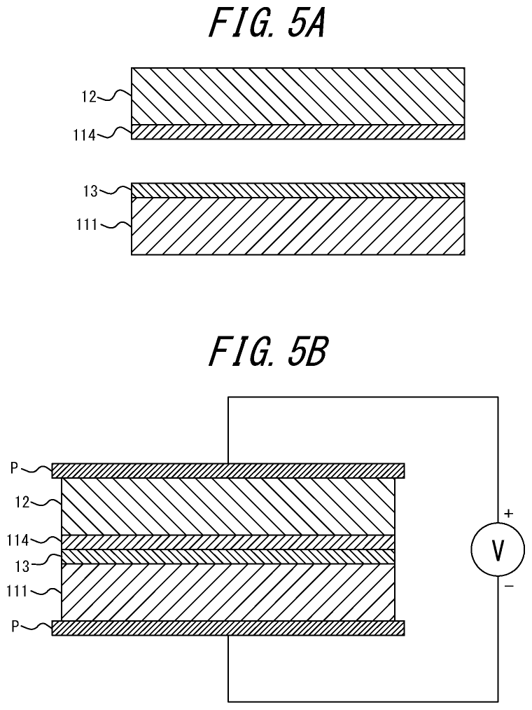

As with Example 3, the base plate and the cooling plate constituting the power module were joined together. However, as illustrated in FIG. 5A, the plating layer 114 was made of gold. Here, a natural oxide film was not formed on the plating layer 114. Then, as illustrated in FIG. 5B, the base plate 111 and the power module substrate 12 were arranged so that they are in contact with each other via the oxygen ion conductor layer 13 and the plating layer 114. Subsequently, the base plate 111 was brought in contact with the electrode plate P connected to the negative electrode side of the voltage application device V and the power module substrate 12 was brought in contact with the electrode plate P connected to the positive electrode side of the voltage application device V, and a DC voltage was applied in the same manner as Example 3. As a result, the base plate 111 and the power module substrate 12 were firmly joined together (anode bonding).

### Example 5

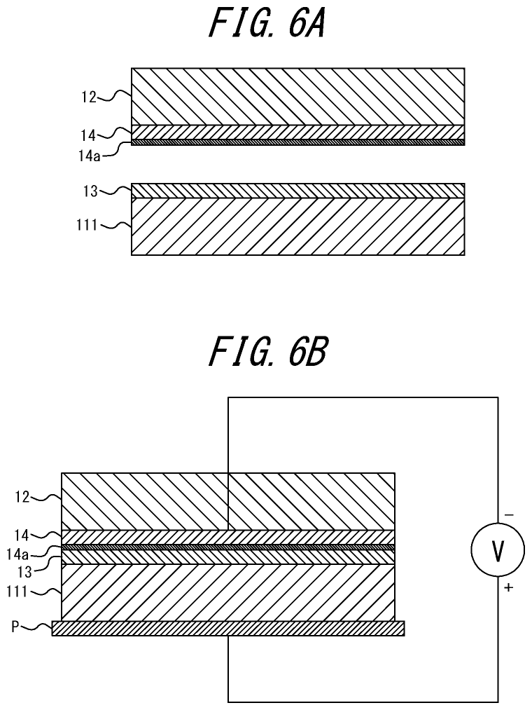

As with Example 3, the base plate and the power module substrate constituting the power module were joined together. However, as illustrated in FIG. 6B, a through hole that passes through the base plate 111 was formed, and the plating layer 14 was directly connected to the negative electrode side of the voltage application device V and the base plate 111 was brought in contact with the electrode plate P connected to the positive electrode side of the voltage application device V. Then, with the base plate 111, the power module substrate 12 and the oxygen ion conductor layer 13 heated to 300° C., a DC voltage of 100V was applied between the base plate 111 and the power module substrate 12. As a result, the base plate 111 and the power module substrate 12 were firmly joined together. In this example, compared to Example 3, they were joined together at a lower temperature and in a shorter period of time (cathode bonding).

### Example 6

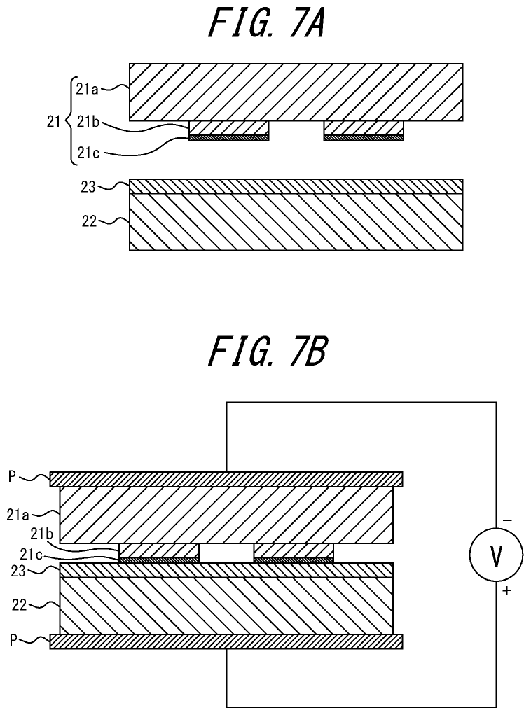

The circuit boards constituting the multilayer circuit board of the power module were joined together. First, as illustrated in FIG. 7A, the internal wiring layer 21b made of copper or aluminum was formed on the surface of the substrate 21a made of alumina to constitute a circuit board 21. Here, the natural oxide film 21c made of copper or aluminum constituting the internal wiring layer 21b was formed on the surface of the internal wiring layer 21b. Then, the oxygen ion conductor layer 23 made of YSZ was formed on the surface of the adjacent circuit board 22. Next, as illustrated in FIG. 7B, the circuit board 21 was brought in contact with the electrode plate P connected to the negative electrode side of the voltage application device V, and the circuit board 22 was brought in contact with the electrode plate P connected to the positive electrode side of the voltage application device V. Then, with the circuit boards 21, 22 and the oxygen ion conductor layer 23 heated to 500° C., a DC voltage of 100V was applied between the circuit board 21 and the circuit board 22. As a result, the circuit board 21 and the circuit board 22 were firmly joined together. In this manner, according to the present invention, circuit boards of the multilayer circuit board constituting the power module can be firmly joined together. Further, since the internal wiring layer can be changed in an assembly step, the degree of freedom in design and manufacturing can be improved.

### Example 7

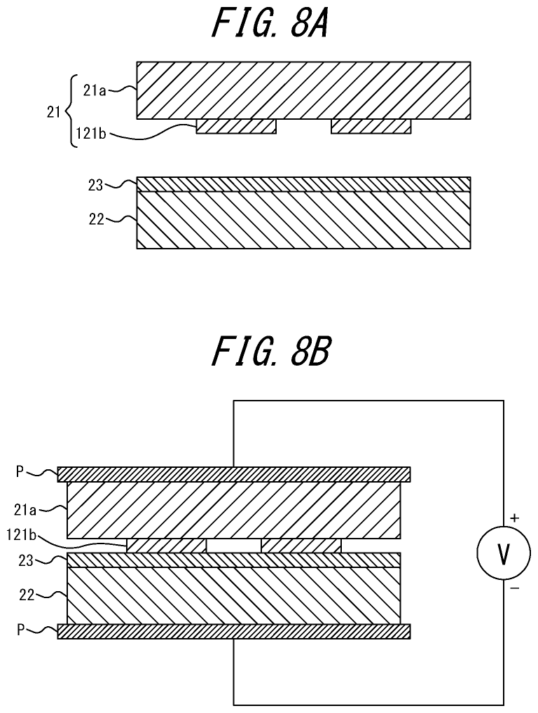

As with Example 6, the circuit boards constituting the multilayer circuit board of the power module were joined together. However, as illustrated in FIG. 8A, the internal wiring layer 121b was made of gold plating, and a natural oxide film was not formed on the surface thereof. Further, as illustrated in FIG. 8B, the circuit board 21 was brought in contact with the electrode plate P connected to the positive electrode side of the voltage application device V, and the circuit board 22 was brought in contact with the electrode plate P connected to the negative electrode side of the voltage application device V, then a DC voltage was applied in the same manner as Example 6. As a result, the circuit board 21 and the circuit board 22 were firmly joined together (anode bonding).

### Example 8

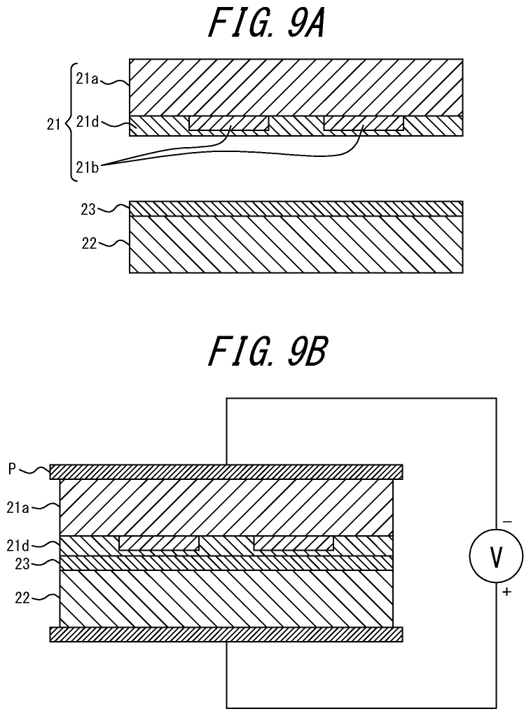

As with Example 6, the circuit boards constituting the multilayer circuit board of the power module were joined together. However, as illustrated in FIG. 9A, the internal wiring layer 21b was covered with the glass frit layer 21d formed by softening and then curing a glass frit. Then, as illustrated in FIG. 9B, a DC voltage was applied in the same manner as Example 6. As a result, the circuit board 21 and the circuit board 22 were firmly joined together (cathode bonding). In this manner, the glass frit layer 21d allows formation of a gap-free joint around the internal wiring layer 21b, and reliability of external forces and resistance to weather can be improved.

### Example 9

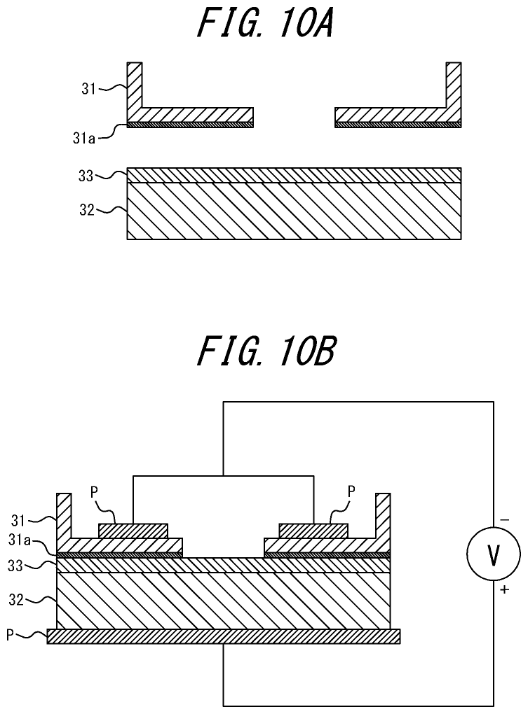

The external connection terminal and the circuit board constituting the power module were connected together. First, two external connection terminals 31 made of Cu and the circuit board 32 made of alumina were prepared. Here, the natural oxide film 31a was formed on the surface of the external connection terminals 31. Then, as illustrated in FIG. 10A, the oxygen ion conductor layer 33 made of YSZ was formed on the surface of the circuit board 32. Next, as illustrated in FIG. 10B, the external connection terminals 31 were brought in contact with the electrode plates P connected to the negative electrode side of the voltage application device V, and the circuit board 32 was brought in contact with the electrode plate P connected to the positive electrode side of the voltage application device V. Then, with the external connection terminals 31, the circuit board 32 and the oxygen ion conductor layer 33 heated to 500° C., a DC voltage of 100V was applied between the external connection terminals 31 and the circuit board 32. As a result, the external connection terminals 31 and the circuit board 32 were firmly joined together. In this manner, according to the present invention, the external connection terminals and the circuit board constituting the power module can be firmly joined together, connection between wiring and terminal is facilitated, and the degree of freedom in design and manufacturing can be improved.

According to the present invention, even if an area of the joining surface is large, power module components can be firmly joined together.

### REFERENCE SIGNS LIST

11, 111 Base plate
11a,14a,21c Natural oxide film
12 Power module substrate
13,23,33 Oxygen ion conductor layer
14,114 Plating layer
14a Natural oxide film
21,22,32 Circuit board
21a Substrate
21b,121b Internal wiring layer
21d Glass frit layer
31 External connection terminal
P Electrode plate
V Voltage application device

1. A joining method, comprising:
an oxygen ion conductor layer formation step of forming an oxygen ion conductor layer on a surface of one of a first member to be joined containing metal and a second member to be joined containing ceramic;
an arrangement step of arranging the first member to be joined and the second member to be joined so that they are in contact with each other via the oxygen ion conductor layer;
a connection step of connecting the first member to be joined to a negative electrode side of a voltage application device and the second member to be joined to the positive electrode side of the voltage application device; and
a voltage application step of applying a voltage between the first member to be joined and the second member to be joined to join the first member to be joined and the second member to be joined, wherein:
the first member to be joined has an oxide layer on a surface thereof;
in the oxygen ion conductor layer formation step, the oxygen ion conductor layer is formed on the second member to be joined; and
in the arrangement step, the first member to be joined and the second member to be joined are arranged so that they are in contact with each other via the oxide layer and the oxygen ion conductor layer.

2. (canceled)

3. (canceled)

4. The joining method according to claim 1, wherein:
the first member to be joined has a metal plating layer on a surface thereof, and the metal plating layer has the oxide layer on a surface thereof;
in the arrangement step, the first member to be joined and the second member to be joined are arranged so that they are in contact with each other via the oxide layer and the oxygen ion conductor layer.

5. (canceled)

6. (canceled)

7. The joining method according to claim 1, wherein:
the first member to be joined has an internal wiring layer containing metal on a surface thereof, and the oxide layer is provided on a surface of the internal wiring layer;
in the arrangement step, the first member to be joined and the second member to be joined are arranged so that they are in contact with each other via the oxygen layer and the oxygen ion conductor layer.

8. (canceled)

9. The joining method according to claim 1, wherein:
the first member to be joined has an internal wiring layer containing metal on a surface thereof and a glass frit layer as the oxide layer that covers the internal wiring layer and is formed by softening and then curing a glass frit composed of silicon oxide;
in the arrangement step, the first member to be joined and the second member to be joined are arranged so that they are in contact with each other via the oxygen ion conductor layer and the glass frit layer.

10. The joining method according to claim 1, wherein the voltage application step is performed at a temperature at which a resistivity ρ(Ω·cm) of the ceramic is given by the following equation (A):
$$ρ = \frac{Vt}{qdNs} , \qquad ( A )$$
where q is an elementary charge (1.6×10−¹⁹(C)), d is a thickness of the ceramic (cm), Ns is an atomic planar density (cm−²) of a surface of the oxygen ion conductor, V is a voltage (V) applied between the first member to be joined and the second member to be joined, and t is joining time (s).
